(19) United States
(12) Patent Application Publication
(10) Pub. No.: US 2011/0304054 A1
(43) Pub. Date: Dec. 15, 2011

(54) SEMICONDUCTOR DEVICE AND METHOD OF FABRICATING THE SAME

(75) Inventor: Takayuki Sakai, Tokyo (JP)

(73) Assignee: KABUSHIKI KAISHA TOSHIBA, Tokyo (JP)

(21) Appl. No.: 13/051,193

(22) Filed: Mar. 18, 2011

(30) Foreign Application Priority Data
Jun. 14, 2010 (JP) P2010-134938

(51) Int. Cl. H01L 23/48; H01L 21/20; H01L 21/302

(52) U.S. Cl. 257/774; 438/700; 438/478; 257/E23.011; 257/E21.214; 257/E21.09

(57) ABSTRACT

According to one embodiment, a semiconductor device including a conductive layer formed in a trench formed in a semiconductor substrate via an insulating film, an opening portion of the trench being formed with a plurality of interconnected concaves and with a curved surface as a folding fan so as to set to be the opening portion gradually wider from a sidewall of the trench towards a surface of the semiconductor substrate.

### CROSS REFERENCE TO RELATED APPLICATION

This application is based upon and claims the benefit of priority from prior Japanese Patent Application No. 2010-134938, filed on Jun. 14, 2010, the entire contents of which are incorporated herein by reference.

### FIELD

Exemplary embodiment described herein generally relates to a semiconductor device and a method of fabricating the semiconductor device.

### BACKGROUND

In a semiconductor device with a trench structure, for example, in an insulated-gate field effect transistor with a trench gate (hereinafter, referred to as a trench MOS transistor), the trench is formed in a semiconductor substrate to be substantially perpendicular to a surface of the semiconductor substrate. Accordingly, each corner portion of the trench opening has a substantially right angle. When the corner portion has a right angle, a gate insulation film formed on the corner portion is made thin and electric-field concentration is more likely to occur in the corner portion.

Consequently, breakdown voltage of the trench structure is decreased, and reliability of the trench MOS transistor is lowered.

In conventional trench MOS transistors, a corner portion of the trench opening is rounded to have a shape controlled to make the electric-field concentration less likely to occur, and thus breakdown voltage of the trench structure is improved.

The shape is controlled mainly by combining an anisotropic etching process and an isotropic etching process.

For example, there is a method in which a trench is firstly formed by an anisotropic etching process, and then a trench-opening portion with a tapered shape is formed by performing an isotropic etching process with a masking material receded from the trench.

In addition, there is another method in which an opening portion with a tapered shape is formed firstly by an isotropic etching process, and then a trench is formed by an anisotropic etching process.

Each of these methods, however, needs a large amount of isotropic etching to obtain a satisfactory tapered shape.

For this reason, the angle made by the trench-opening portion with the surface of the semiconductor substrate approximates a right angle, so that electric-field concentration is more likely to occur in the corner portion. In this case, there is a problem that gate breakdown voltage is lowered when the gate insulation film is made thinner to get a low on-resistance as a device characteristic.

In addition, when the internal surface of the trench is not isotropically etched, a damaged layer remains on the internal surface of the trench. The remaining damaged layer causes another problem of deteriorating the insulating performance of the gate insulation film which is formed later, and thereby lowering reliability of the trench MOS.

Accordingly, there is a demand to achieve improvement in the shape of the trench opening with a satisfactory tapered shape while maintaining the shape of trench.

### BRIEF DESCRIPTION OF THE DRAWINGS

FIG. 1 is a cross-sectional view illustrating a semiconductor device according to an embodiment;

FIG. 2 is an enlarged cross-sectional view illustrating a principal portion of the semiconductor device according to the embodiment;

FIG. 3 is a cross-sectional view sequentially illustrating the principal portion of the semiconductor device according to the embodiment;

FIG. 4 is a cross-sectional view sequentially illustrating the principal portion of the semiconductor device according to the embodiment;

FIG. 5 is a cross-sectional view sequentially illustrating the principal portion of the semiconductor device according to the embodiment;

FIG. 6 is a cross-sectional view sequentially illustrating the principal portion of the semiconductor device according to the embodiment;

FIG. 7 is a cross-sectional view sequentially illustrating the principal portion of the semiconductor device according to the embodiment;

FIG. 8 is a sectional view sequentially illustrating a principal portion of the semiconductor device according to the embodiment of the invention.

FIG. 9 is a cross-sectional view illustrating the principal portion of the semiconductor device of a comparative example according to the embodiment.

### DETAILED DESCRIPTION

According to one embodiment, a semiconductor device including a conductive layer formed in a trench formed in a semiconductor substrate via an insulating film, an opening portion of the trench being formed with a plurality of interconnected concaves and with a curved surface as a folding fan so as to set to be the opening portion gradually wider from a sidewall of the trench towards a surface of the semiconductor substrate.

An embodiment will be described below in detail with reference to the attached drawings mentioned above.

### EMBODIMENT

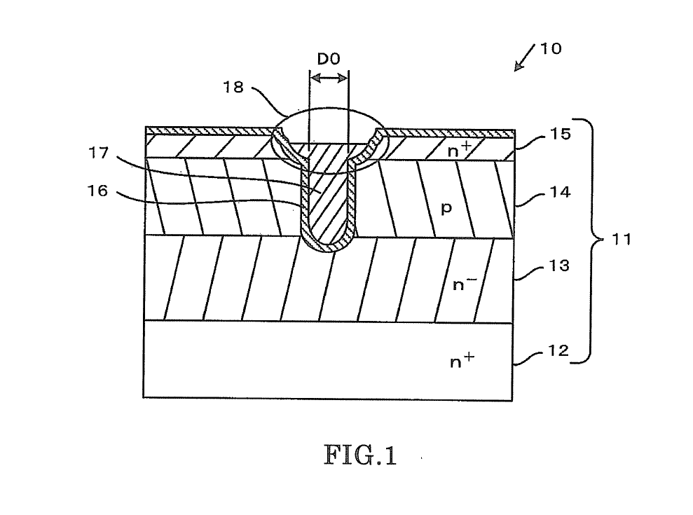

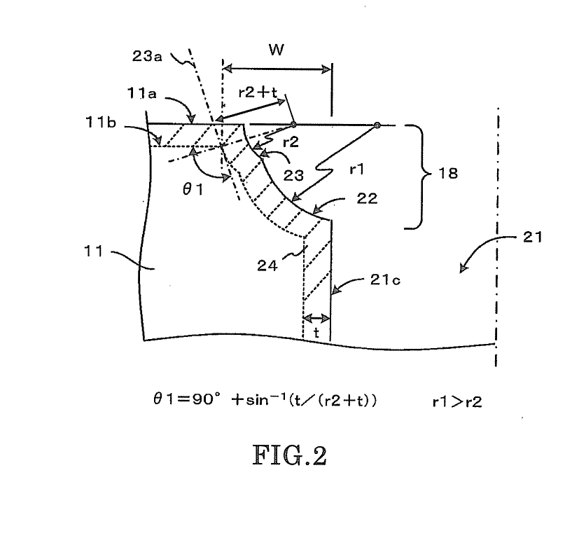

A semiconductor device of the embodiment will be described with reference to FIGS. 1 and 2. FIG. 1 is a cross-sectional view illustrating a semiconductor device according to the embodiment. FIG. 2 is an enlarged cross-sectional view illustrating a principal portion of the semiconductor device. The embodiment is an example of a case where the semiconductor device is a vertical-type MOS transistor with a trench gate (trench MOS transistor).

As shown in FIG. 1, a semiconductor device 10 of the embodiment is formed in a semiconductor substrate 11. The semiconductor substrate 11 includes an n-type silicon substrate 12, an n-type first semiconductor layer 13 formed on the n-type silicon substrate 12, a p-type second semiconductor layer 14 formed on the n-type first semiconductor layer 13, and an n-type third semiconductor layer 15 formed on the p-type second semiconductor layer 14.

A trench is formed in the semiconductor substrate 11 so as to penetrate both the third semiconductor layer 15 and the second semiconductor layer 14 until reaching the first semiconductor layer 13. In the trench, a gate electrode 17 (conductive layer) is formed via a gate insulation film 16 (insulating film) formed in between. The trench is formed in a stripe shape extending in the lengthwise direction (i.e., direction that is perpendicular to the sheet surface of FIG. 1), for example.

The n-type silicon substrate 12 is a drain layer. The n-type first semiconductor layer 13 is a drift layer where electrons passing through a channel are carried. The p-type second semiconductor layer 14 is a channel layer where a channel is formed. The n-type third semiconductor layer 15 is a source layer.

An interlayer insulating film (not illustrated) is formed on the third semiconductor layer 15. Both a source electrode (not illustrated) and a gate wiring (not illustrated) are formed on the interlayer insulating film. The source electrode passes through an opening formed in the interlayer insulating film, and is connected to the third semiconductor layer 15. The gate wiring is connected to the gate electrode 17. A drain electrode (not illustrated) is formed on the entire surface of the n-type silicone substrate 12.

An opening portion 18 of the trench has a shape formed with interconnected plural concaves. The shape is a curved surface extending so that the opening portion gradually becomes wider from each sidewall of the trench towards the surface of the semiconductor substrate 11. More details of the shape of the opening portion 18 will be discussed later.

FIG. 2 is an enlarged cross-sectional view illustrating the opening portion of the trench. FIG. 2 shows only the left-half of the opening portion of the trench. As illustrated in FIG. 2, the opening portion 18 of a trench 21 has a shape formed with interconnected plural concaves (here, a concave 22 and a concave 23). The shape is a curved surface to be the opening portion gradually wider from an internal surface 21c (sidewall) of the trench 21 towards a surface 11a of the semiconductor substrate 11.

Each of the concaves 22, 23 has a substantially arc shape. The center of the arc of each of the concaves 22, 23 is substantially on the same plane that the surface 11a of the semiconductor substrate 11 is on. The concave 22, which is on the side near the semiconductor substrate 11, has a curvature radius r1 set to be larger than the curvature radius r2 of the concave 23, which is on the side near the opening portion (r1>r2).

The area hatched with broken lines is a thermally-oxidized area 24 formed by the transformation of the silicon material of the internal surface 21c of the trench 21 when the internal surface 21c of the trench 21 is thermally oxidized to form the gate insulation film 16. The thermally-oxidized area 24 is an area which forms a part of the gate insulation film 16.

An angle θ1 represents the angle of a corner portion where the opening portion 18 of the trench 21 intersects with a surface 11b of the semiconductor substrate 11 after the formation of the gate insulation film 16. To put it differently, the angle θ1 is an angle formed at the intersection of the concave 23 with the surface 11b of the semiconductor substrate 11 by a tangential line 23a of the concave 23 and the surface 11b of the semiconductor substrate 11. The angle θ1 is expressed by the following equation where t is the thickness of the thermally-oxidized area 24 and r2 is the curvature radius of the concave 23.

θ1=90°+sin⁻¹(t/(r2+t)) (1)

As the corner portion of the trench forms a gentler slope, the electric-field concentration on the trench structure is relieved, and greater improvement is achieved in breakdown voltage of the trench structure. Accordingly, a larger angle θ1 of the opening portion 18 of the trench 21 is more preferable.

To make the angle θ1 of the corner portion of the opening portion 18 large enough relative to the width W of the opening portion 18, the opening portion 18 of the semiconductor device 10 of the embodiment has a shape of a dual-concave structure formed by the interconnected concaves 22, 23. The shape of the opening portion 18 is formed to make the angle θ1 of the corner portion of the opening portion 18 as large as probable relative to a given width W of the opening portion.

Accordingly, the angle θ1 can be made larger than in a case of the opening portion 18 with a single-concave structure, so that the electric-field concentration can be attenuated. Consequently, even when the gate insulation film is made thinner, a higher gate breakdown voltage can be obtained.

The opening portion 18 with a dual-concave structure including the interconnected concaves 22, 23 can be formed in the following manner. Firstly, a trench is formed by an anisotropic etching process using a masking material. Then, a process of making the masking material recede outwards and a process of isotropic etching are repeated. More details of the formation of the opening portion 18 will be described later. By the isotropic etching process, the internal surface of the trench 21 recedes outwards and the portion of the semiconductor substrate 11 right below the masking material is undercut. Thus the interconnected concaves 22, 23 are formed.

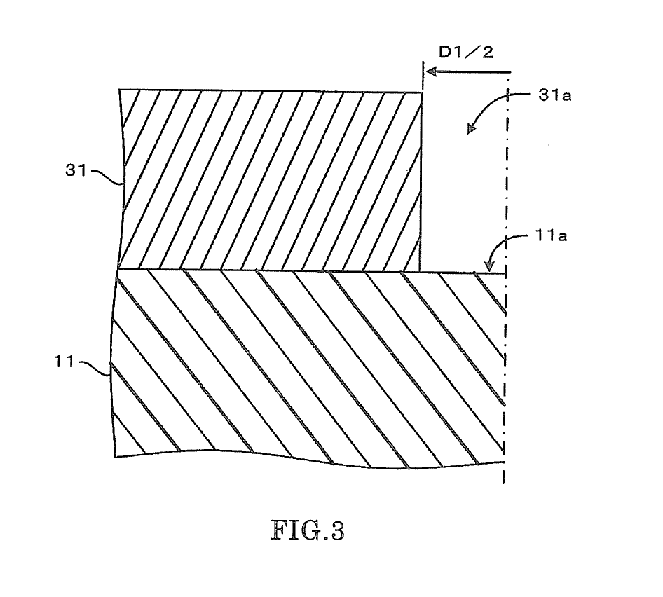

Next, a method of fabricating the semiconductor device 10 will be described. FIGS. 3 to 8 are cross-sectional views sequentially illustrating a principal portion of the semiconductor device 10 in fabrication processes. As shown in FIG. 3, a silicon-oxide film with a thickness of approximately 200 nm is firstly formed on the semiconductor substrate 11 by a thermally oxidizing process, for example. The silicon-oxide film thus formed is an insulating film 31 which is used as a masking material.

Then, a resist film (not illustrated) is formed on the insulating film 31 by a photolithography process. The resist film has an opening with a width D1 that is narrower than a width D0 which is eventually required as the trench needs. Using the resist film as a mask, a first opening 31a with a width D1 is formed in the insulating film 31 by a RIE (reactive ion etching) process using a fluorine-based gas. Thus, the surface 11a of the semiconductor substrate 11 is exposed.

Note that the semiconductor substrate 11 is formed in the following way, for example. First, an n-type silicon epitaxial layer is formed in the n-type silicon substrate 12. Next, a double ion-implantation process is performed, in which ions of boron (B) are firstly implanted deeply into the n-type silicon epitaxial layer, and then ions of phosphorus (P) are shallowly implanted into the n-type silicon epitaxial layer.

The implantation of boron ions turns the conductivity type of the silicon epitaxial layer from an n-type to a p-type. The implantation of phosphorus ions turns the conductivity type of the silicon epitaxial layer, which is now the p-type, back to an n-type.

Accordingly, the lower portion of the n-type silicon epitaxial layer becomes the n-type first semiconductor layer 13. The middle portion of the n-type silicon epitaxial layer becomes the p-type second semiconductor layer 14. The upper portion of the n-type silicon epitaxial layer becomes the n-type third semiconductor layer 15.

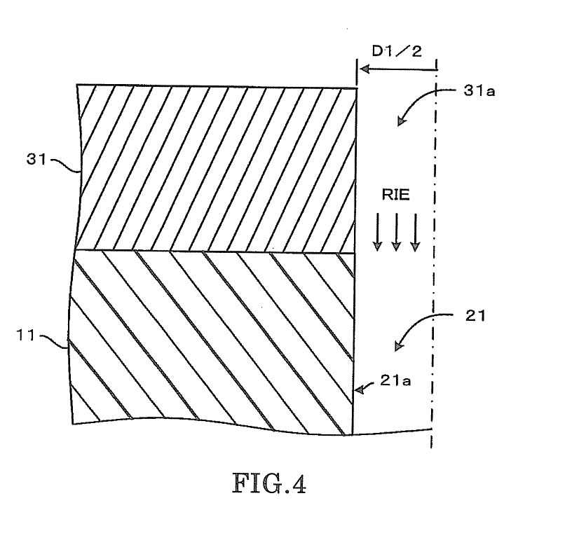

Then, as shown in FIG. 4, using the insulating film 31 with the first opening 31a as a mask, the semiconductor substrate 11 is anisotropically etched in a RIE process using a chlorine/fluorine-based gas supplied through the first opening 31a. Thus, the trench 21 is formed with a depth of approximately 10 μm.

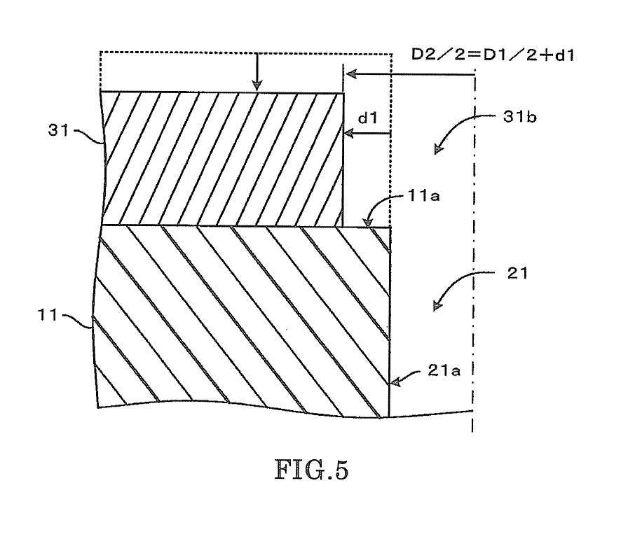

Then, as shown in FIG. 5, a wet etching process is performed by using a hydrofluoric acid-based chemical solution, for example, a buffered hydrofluoric acid (BHF) prepared by mixing a hydrofluoric acid (HF) and ammonium fluoride (NH₄F). In the wet etching process, as the thickness of the insulating film 31 is gradually decreased, each end portion of the first opening 31a of the insulating film 31 is made to retreat outwards by a distance d1. Thus, a second opening 31b with a width D2 that is larger than the width D1 of the first opening 31a (D2=D1+2d1) is formed. Thus, the surface 11a of the semiconductor substrate 11 is exposed around the trench 21.

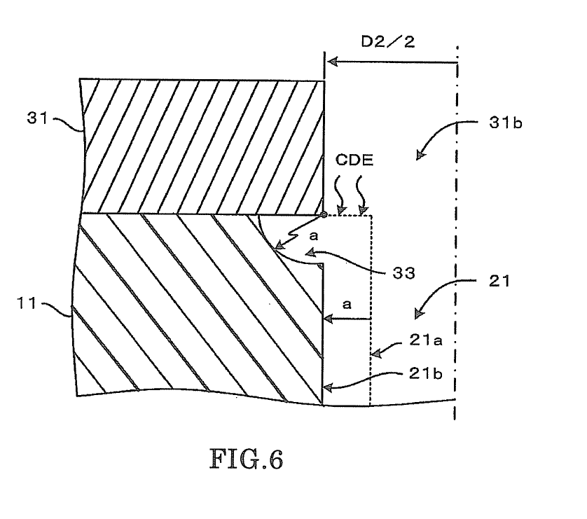

Next, as shown in FIG. 6, an isotropic etching process is performed by a CDE (chemical dry etching) method using a chlorine/fluorine-based gas, for example. Thus, an internal surface 21a of the trench 21 is made to retreat outwards and a concave 33 is formed so as to extend towards the interface between the insulating film 31 and the semiconductor substrate 11.

The concave 33 is formed by the undercutting of a portion of the semiconductor substrate 11 right below the insulating film 31. The undercutting occurs due to the following reasons, for example. The upper portion of the semiconductor substrate 11 is etched earlier. The concentration of un-reacted etching gas is higher.

Assuming that the internal surface 21a of the trench 21 retreats outwards by an amount a (hereinafter referred to as the retreating amount a), the semiconductor substrate 11 is undercut by an amount approximately equal to the receding amount a. The shape of the concave 33 approximates an arc with a curvature radius which is equal to the receding amount a. The center of the arc of the concave 33 is an end portion of the second opening 31b of the insulating film 31.

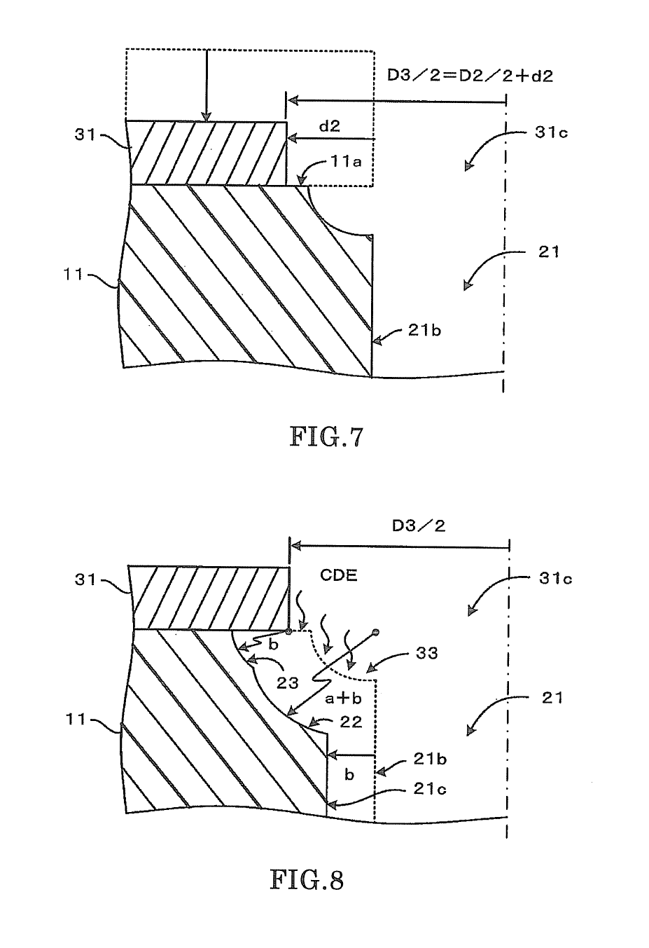

Next, the processes shown in FIGS. 5 and 6 are repeated by a predetermined number of times (specifically, each process is repeated once in the embodiment). Specifically, as shown in FIG. 7, by a wet etching process like the one as shown in FIG. 5, each end portion of the second opening 31b of the insulating film 31 is made to retreat outwards by a distance d2. Thus, a third opening 31c with a width D3 which is larger than the width D2 of the second opening 31b (D3=D2+2d2) is formed. Thus, the surface 11a of the semiconductor substrate 11 is exposed around the trench 21.

Then, as shown in FIG. 8, an isotropic etching process like the one as shown in FIG. 6 is performed by the CDE method so that the internal surface 21b of the trench 21 recedes outwards. In this process, the concave 33 also retreats outwards to form the concave 22. Thus, the concave 23 is formed so as to extend towards the interface between the insulating film 31 and the semiconductor substrate 11.

Assuming that the internal surface 21b of the trench 21 retreats outwards by an amount b (hereinafter referred to as the retreating amount b), the semiconductor substrate is undercut by an amount approximately equal to the retreating amount b. The shape of the concave 22 approximates an arc with a curvature radius that is equal to the sum of the retreating amount a and the retreating amount b (i.e., the curvature radius=a+b). The shape of the concave 23 approximates an arc with a curvature radius which is equal to the retreating amount b. The center of the arc of the concave 23 is an end portion of the third opening 31c of the insulating film 31.

In such a manner, the shape of the opening portion 18 of the trench 21 is formed with the interconnected concaves 22, 23. The shape is a curved surface to be the opening portion gradually wider from each internal surface 21c (sidewall) of the trench 21 towards the surface 11a of the semiconductor substrate 11. The curvature radius a+b and the curvature radius b correspond respectively to the curvature radiuses r1, r2 as shown in FIG. 2 (r1=a+b, r2=b).

Subsequently, the insulating film 31 is removed. Then, a silicon-oxide film with a thickness of approximately 30 nm is formed, as a gate insulation film 16, in the internal surface including the opening portion of the trench 21 by a thermally oxidizing process, for example. In this process, an insulating film with the same thickness as that of the gate insulation film 16 is also formed on the surface of the semiconductor substrate 11.

Next, a poly-crystalline silicon film is filled in the trench 21 by a CVD (chemical vapor deposition) process, for example. Thus, the gate electrode 17 is formed. Then, a silicon nitride film is formed, as an interlayer insulating film, both on the insulating film on the semiconductor substrate 11 and on the gate electrode 17, by plasma CVD process, for example.

Then, a source electrode and a gate wiring are formed on the interlayer insulating film. The source electrode is connected to the third semiconductor layer 15 through the opening formed in the interlayer insulating film. The gate wiring is connected to the gate electrode 17 in the same manner. In addition, a drain electrode is formed on the entire surface of the n-type silicone substrate 12. Thus, the semiconductor device 10 as shown in FIG. 1 is obtained

According to the method of fabricating the semiconductor device 10 of the embodiment, a dual-concave structure including the interconnected concaves 22, 23 is formed in the opening portion 18 of the trench 21. Here, control is exercised over the conditions for the isotropic etching process (the retreating amounts d1, d2 of the masking material and the receding amounts a, b of the internal surface of the trench), the thickness t of the thermally-oxidized area 24 and so on.

Accordingly, the damaged layer of the internal surface 21c of the trench 21 is removed efficiently, and a width D0 which is eventually required as the trench can be obtained. Thus, it is possible to achieve both improvement in the shape of the opening 18 of the trench 21 and maintenance of the shape of trench 21.

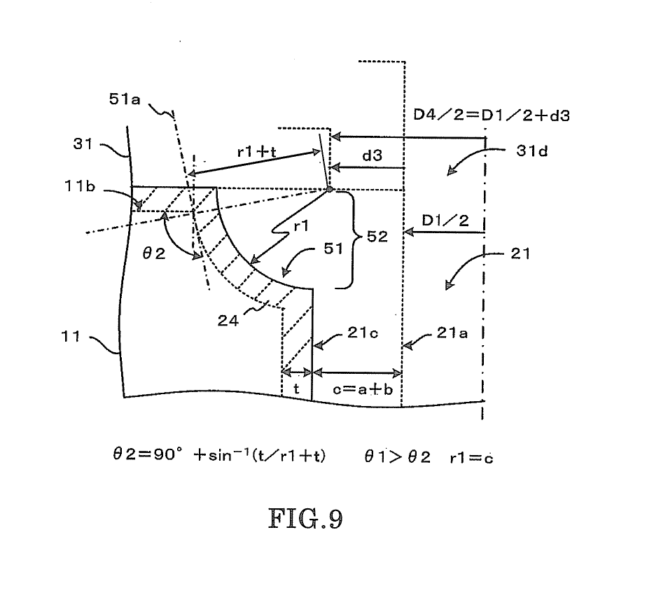

FIG. 9 is a cross-sectional view illustrating an opening portion of a trench of a comparative example. Here, the opening portion of the trench of the comparative example has a shape formed by a single anisotropic etching process and a single isotropic etching.

The opening portion of the trench of the comparative example is formed basically in the same processes as shown in FIGS. 3 to 6. The differences are as follows. First, the retreating amount of the insulating film 31 in the process shown in FIG. 5 is changed from d1 to d3. Next, the retreating amount of the internal surface 21a of the trench 21 in the process shown in FIG. 6 is changed from a to c=a+b.

As shown in FIG. 9, the trench 21 with a width D1 is formed in the semiconductor substrate 11 by an anisotropic etching process like the one shown in FIGS. 3 and 4.

Next, each end portion of the first opening 31a of the insulating film 31 is made to retreat outwards by a distance d3 by a wet etching process like the one shown in FIG. 5. Thus, a fourth opening 31d with a width D4 which is larger than the width D1 of the first opening 31a (D4=D1+2d3) is formed.

Then, an isotropic etching process is performed as shown in FIG. 6, so that the internal surface 21a of the trench 21 is made to retreat outwards by c=a+b and a concave 51 is formed so as to extend towards the interface between the insulating film 31 and the semiconductor substrate 11.

The shape of the concave 51 approximates an arc with a curvature radius which is equal to the receding amount c of the internal surface 21a of the trench 21. The center of the arc of the concave 51 is an end portion of the fourth opening 31d of the insulating film 31.

An opening portion 52 of the trench 21 of the comparative example has a shape which is formed by the single concave 51. An angle θ2 represents the angle of a corner portion where the opening portion 52 of the trench 21 intersects with the surface 11b of the semiconductor substrate 11 after the formation of the gate insulation film 16. To put it differently, the angle θ2 is an angle formed at the intersection of the concave 51 with the surface 11b of the semiconductor substrate 11 by a tangential line 51a of the concave 51 and the surface 11b of the semiconductor substrate 11. The angle θ2 is expressed by the following equation where t is the thickness of the thermally-oxidized area 24 and r1 is the curvature radius of the concave 51.

θ2=90°+sin⁻¹(t/(r1+t)) (2)

Accordingly, the angle θ1 of the corner portion of the opening portion 18 of the trench 21 formed by the interconnected concaves 22, 23 of the embodiment shown in FIG. 2 is larger than the angle θ2 of the corner portion of the opening portion 52 of the trench 21 of the comparative example shown in FIG. 9 (θ1>θ2). This is because the curvature radius r2 of the concave 23 is smaller than the curvature radius r1 of the concave 51 (r1>r2).

Accordingly, the angle θ1 of the embodiment can be made larger than in the case where the opening portion 18 has a single-concave structure. Hence, the electric-field concentration can be relieved. Consequently, even when the gate insulation film is made thinner, a high gate breakdown voltage can be obtained.

As has been described thus far, in the embodiment, the trench 21 is formed in the semiconductor substrate 11, and the opening portion 18 of the trench 21 has a shape formed with the interconnected concaves 22, 23. The shape is a curved surface to be the opening portion gradually wider from each sidewall 21a of the trench 21 towards the surface 11a of the semiconductor substrate 11.

Accordingly, a larger angle θ of the corner portion of the opening portion can be obtained for a prescribed width W of the opening portion. Consequently, a semiconductor device having a trench structure with high breakdown voltage can be obtained with a method of fabricating the semiconductor device.

In the embodiment, the description has been given of the case where the opening portion 18 of the trench 21 is formed by two interconnected concaves 22, 23, but the number of the concaves is not limited to two. As the number of concaves becomes larger, the angle of the corner portion of the opening portion becomes larger for a prescribed width W of the opening portion. A larger number of concaves, however, mean a larger number of fabrication processes. Accordingly, the number of concaves is desirably a minimum one for obtaining the required angle θ of the corner portion.

In addition, the description has been given of the case where the semiconductor device is a trench MOS transistor. The invention, however, is applicable to semiconductor devices of other types with a trench structure and requiring high breakdown voltage. For example, the embodiment is applicable also to an IGBT (insulated gate bipolar transistor) with a trench gate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a conductive layer formed in a trench formed in a semiconductor substrate via an insulating film, an opening portion of the trench being formed with a plurality of interconnected concaves and with a curved surface to be the opening portion gradually wider from a sidewall of the trench towards a surface of the semiconductor substrate.

2. The semiconductor device of claim 1, wherein
each of the interconnected concaves has an arc shape, and
one of the concaves formed at a side nearer the semiconductor substrate has a larger curvature radius than another of the concave formed at a side nearer the opening portion.

3. The semiconductor device of claim 1, wherein
the insulating film is formed by a reaction of the semiconductor substrate, and the semiconductor substrate is consumed in the reaction.

4. The semiconductor device of claim 1, wherein
an angle in a corner portion where the opening portion of the trench intersects with the surface of the semiconductor substrate is expressed as 90°+sin⁻¹(t/(r+t)), where t is a thickness of the surface of the semiconductor substrate consumed in the reaction for the insulating film, and r is a curvature radius of the concave of the plurality of concaves that intersects with the surface of the semiconductor substrate.

5. The semiconductor device of claim 1, wherein
the opening portion of the trench has a structure with two of the concaves.

6. The semiconductor device of claim 1, wherein
the semiconductor substrate includes an n⁺-layer, a p-layer, an n⁻-layer, and an n⁺-layer which are formed in an order from a surface side of the semiconductor substrate, and a bottom portion of the trench is in the n⁻-layer.

7. A method of fabricating a semiconductor device, comprising:
forming a trench in a semiconductor substrate by anisotropically etching the using a masking material with a first opening on the semiconductor substrate;
forming a second opening being larger than the first opening by retreating the masking material outwards, and thereby exposing the semiconductor substrate around the trench;
retreating an internal surface of the trench outwards by isotropically etching the semiconductor substrate using the masking material with the second opening and thereby forming a concave extending towards an interface between the masking material and the semiconductor substrate; and
repeating exposing the semiconductor substrate and forming the concave.

8. The method of claim 7, wherein
the concave is formed to have an arc shape with a curvature radius substantially equal to a receding amount of the internal surface of the trench in forming the concave.

9. The method of claim 7, wherein
a receding amount of the concave is accumulated in repeating to form the concave.

10. The method of claim 7, wherein
repeating to expose the semiconductor substrate and to form the concave is performed one cycle.

11. The method of claim 7, further comprising:
forming an insulating film on a surface of the semiconductor substrate by a thermally-oxidizing reaction after repeating exposing the semiconductor substrate and forming the concave.

12. The method of claim 7, wherein
forming the concave is controlled so that an angle of a corner portion where an opening portion of the trench intersects with a surface of the semiconductor substrate is expressed as 90°+sin⁻¹(t/(r+t)), where t is a thickness of the surface of the substrate consumed in the reaction for the insulating film, and r is a curvature radius of one of the concave which intersects with the surface of the semiconductor substrate.

13. The method of claim 7, further comprising:
forming a structure in the semiconductor substrate before forming the trench in the semiconductor substrate, the structure including an n⁺-layer, a p-layer, an n⁻-layer, and an n⁺-layer formed in an order from a surface side of the semiconductor substrate.

14. The method of claim 13, wherein
in forming the trench in the semiconductor substrate, a bottom portion of the trench is made to reach the n⁻-layer.
